(19) United States
(12) Patent Application Publication
(10) Pub. No.: US 2024/0150934 A1
(43) Pub. Date: May 9, 2024

(54) POLYSILICON ROD AND METHOD FOR MANUFACTURING POLYSILICON ROD

(71) Applicant: Shin-Etsu Chemical Co., Ltd., Tokyo (JP)

(72) Inventors: Atsushi YOSHIDA, Niigata (JP); Naruhiro HOSHINO, Niigata (JP); Masahiko ISHIDA, Niigata (JP); Takeshi AOYAMA, Niigata (JP); Shigetoshi YAMAGISHI, Niigata (JP); Yoshio KANEKO, Niigata (JP)

(73) Assignee: Shin-Etsu Chemical Co., Ltd., Tokyo (JP)

(21) Appl. No.: 18/501,985

(22) Filed: Nov. 3, 2023

(30) Foreign Application Priority Data
Nov. 8, 2022 (JP) 2022-178646

(51) Int. Cl. C30B 29/06; C30B 25/18; C30B 25/20; C30B 28/14

(52) U.S. Cl. CPC C30B 29/06; C30B 25/186; C30B 25/20; C30B 28/14

(57) ABSTRACT

A polysilicon rod has a diameter of 120 mm or more, the polysilicon rod having a lowest resistivity of 3300 Ωcm or more and an RRG of 100% or less. A polysilicon rod has a diameter of 140 mm or more, the polysilicon rod having a lowest resistivity of 3300 Ωcm or more and an RRG of 150% or less.

### TECHNICAL FIELD

The present invention relates to a polysilicon rod and method for manufacturing a polysilicon rod.

### BACKGROUND ART

Production of a polysilicon rod as a raw material of single crystal silicon is mainly performed by the Siemens process, in which a CVD method is used involving deposition of chlorosilane gas as a raw material in the air by using Joule heat generated when a current flows through a silicon rod (silicon core wire) disposed in an electrode.

The silicon core wire used in the CVD method is cleaned by wet etching (typically nitric acid/hydrogen fluoride) or with ultrapure water for the purpose of removing a damaged layer (fine scratches or surface cracks) formed at the time of shape processing, and impurities and a natural oxide film on the surface are removed simultaneously with the removal of the damaged layer.

After the surface of the silicon core wire is cleaned by wet etching, cleaning, or the like, the silicon core wire is stored in a storage bag, a storage case, or the like until the silicon core wire is disposed in a reactor. At this time, the surface is contaminated by a contact part of the storage bag or the case or particles in the air, and a natural oxide film is formed at the same time. Thus, contact with other substances is managed as short as possible. However, it is inevitable that re-contamination or generation of a natural oxide film occurs because of contact or air before installation in a CVD apparatus.

Examples of currently mainstream single crystal manufacturing processes include the floating zone (FZ) method and the Czochralski (CZ) method. Of these, the FZ method is a method involving dislocation-free growth of a single crystal on a seed crystal side by melting a polysilicon rod from a tip processed into a cone shape by induction coil heating. With the method, high-purity and high-resistance single crystal silicon can be obtained.

### SUMMARY OF INVENTION

### Problem to be Solved by Invention

FIG. 1 is a schematic diagram of the FZ method. A polysilicon rod 1a is inductively heated by a coil 4, melting occurs on the surface of the polysilicon rod 1a, and a melted part 3 is formed in the process of flowing down. An unmelted part 1b often reaches a single crystal silicon 2, which may cause a trouble, and at the same time, the resistivity of the unmelted part 1b which is a part near a center of the polysilicon rod 1a affects the in-plane resistivity distribution of the single crystal silicon (JP H02-283692 A).

As the diameter of the single crystal increases, the unmelted part 1b may remain in the polysilicon rod 1a with its conical tip facing the single crystal silicon side (lower side in FIG. 1) because of the characteristics of the coil 4. The unmelted part 1b, having a projected shape toward the single crystal silicon side, may cause the melted part 3 to solidify at a central part of the single crystal silicon and to be unevenly distributed without extending to the periphery of the single crystal silicon.

Thus, the impurities present in the vicinity of the surface of the silicon core wire tend to be unevenly distributed in the central part of the single crystal silicon as the diameter of the single crystal increases, and the in-plane resistivity distribution (RRG) of the FZ single crystal silicon tends to increase.

As described above, the melt in the vicinity of the center of the melted part tends to stay in the vicinity of the center of the single crystal silicon because the tip of the unmelted part of the polysilicon rod is projected. Since the silicon core wire of the polysilicon rod is usually positioned at the center, the resistivity near the silicon core wire greatly affects the in-plane resistivity distribution of the single crystal silicon. To avoid this, improvements have been made on a FZ apparatus such as shifting the rotation axis of a raw material and a single crystal to make melt asymmetric stirring, as in JP H07-315980 A.

However, while the diameter of the single crystal increases according to a large-diameter FZ method, the thickness of the melt placed on the single crystal (the thickness of the part indicated by reference numeral 3 in FIG. 1) is limited, and a sufficient stirring effect cannot be obtained.

### Means for Solving Problem

It has been found that when a single crystal having a large diameter (120 mm or more) is grown by the FZ method in a common method in order to manufacture high-quality single crystal silicon, the single crystal is strongly affected by a part having a low resistivity of polycrystalline silicon during melting. The inventors of the present disclosure have intensively studied why the low resistance part appears, and found that there is a cause in the vicinity of the surface of the silicon core wire which is the central part of the polycrystalline silicon.

The present invention improves an in-plane resistivity distribution (RRG) of single crystal silicon manufactured by a large-diameter FZ method of 120 mm or more and enables production of high-resistance single crystal silicon having a large diameter by the FZ method by using polysilicon having an improved in-plane resistivity distribution as a raw material.

As a method for manufacturing polycrystalline silicon having improved in-plane resistivity distribution as a raw material, the present application provides a high-purity polysilicon rod and a method for manufacturing the same, for the purpose of improving the in-plane resistivity distribution in a large-diameter FZ method by reducing elution of impurities from a material in a CVD apparatus by subjecting a silicon core wire placed in a reaction furnace to a surface treatment at a temperature within a range not exceeding 1000° C. before a CVD reaction.

WO 2017/221952 and JP S46-002053 A describe that a silicon core wire is set to a temperature higher than 1000° C., and a seed rod is etched with silicon tetrachloride or hydrogen chloride to remove impurities. However, at a temperature higher than 1000° C., a metal surface of a reactor internal structure or the like, silicon tetrachloride and hydrogen chloride, and a by-product chloride react with each other, and impurities such as a dopant are likely to be eluted together with a metal chloride having a high vapor pressure, which may cause contamination of a polysilicon rod. Thus, it is preferable to reduce elution of impurities from the material in the CVD apparatus by preventing the silicon core wire from having a temperature exceeding 1000° C.

In particular, since the supply amount of the raw material is small at the initial stage of the reaction after energization of the silicon core wire, the elution amount of impurities such as metal components and dopants increases as a ratio to the raw material. This finally causes a decrease in resistivity around the silicon core wire in the vicinity of the center of the polysilicon rod, affecting the in-plane resistivity distribution of the polysilicon rod.

The polysilicon rod that improves the in-plane resistance of the single crystal silicon rod in the present invention is provided by the following aspects.

### [Concept 1]

A polysilicon rod according to the present invention may have a diameter of 120 mm or more, the polysilicon rod may have a lowest resistivity of 3300 Ωcm or more and an RRG of 100% or less.

### [Concept 2]

In the polysilicon rod according to concept 1,
the lowest resistivity may be positioned within 30 mm from a silicon core wire toward an outer periphery,
the polysilicon rod may have a highest resistivity at a position of more than 30 mm from the silicon core wire toward the outer periphery.

### [Concept 3]

In the polysilicon rod according to concept 1 or 2,
the RRG may be 50% or less.

### [Concept 4]

A polysilicon rod according to the present invention may have a diameter of 140 mm or more, the polysilicon rod may have a lowest resistivity of 3300 Ωcm or more and an RRG of 150% or less.

### [Concept 5]

In the polysilicon rod according to concept 4,
the lowest resistivity may be positioned within 30 mm from a silicon core wire toward an outer periphery,
the polysilicon rod may have a highest resistivity at a position of more than 30 mm from the silicon core wire toward the outer periphery.

### [Concept 6]

In the polysilicon rod according to concept 4 or 5,
the RRG may be 100% or less.

### [Concept 7]

A method for manufacturing a polysilicon rod according to any one of concepts 1 to 6 may comprise:
a step of setting a silicon core wire in a reactor; and
a step of etching the silicon core wire with a hydrogen halide in a situation where the silicon core wire has a temperature of more than 300° C. but not more than 1000° C.

### [Concept 8]

In the method according to concept 7,
the step of etching with the hydrogen halide may be performed at a temperature of 800° C. or less.

### [Concept 9]

The method according to concept 7 or 8 may further comprise a step of removing an oxide film and impurities on a surface of the silicon core wire by wet etching before setting the silicon core wire in the reactor.

### [Concept 10]

A method for manufacturing a polysilicon rod according to any one of concepts 1 to 6 may comprise:
a step of removing an oxide film and impurities on a surface of a silicon core wire by wet etching;
a step of setting the silicon core wire in a reactor;
a step of etching the silicon core wire with a hydrogen halide in a situation where the silicon core wire has a temperature of more than 300° C. but not more than 800° C.; and
a step of depositing polysilicon through a CVD reaction.

The present invention provides a high-purity polysilicon rod for a FZ raw material having improved in-plane resistivity distribution during single crystallization by an FZ method, and a method for manufacturing the high-purity polysilicon rod.

### BRIEF DESCRIPTION OF DRAWINGS

FIG. 1 is a diagram illustrating a process of producing single crystal silicon from a polysilicon rod;

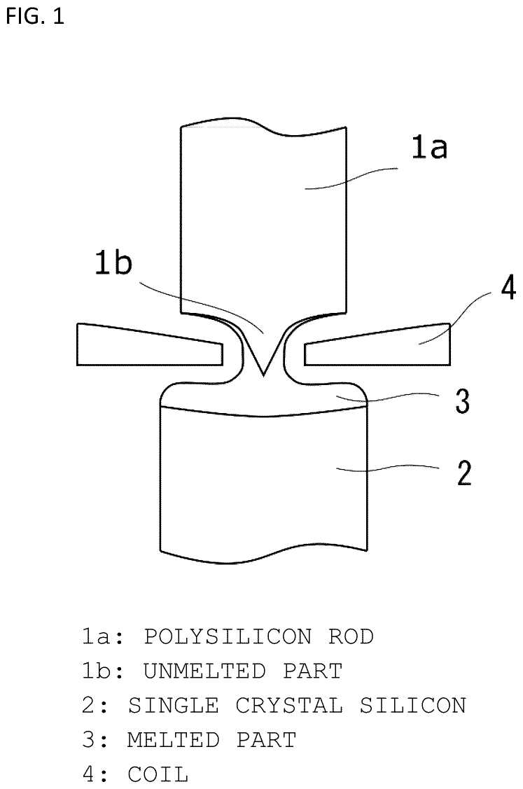

FIG. 2 is a diagram illustrating an aspect of producing a sample;

FIG. 3 is a graph illustrating values of ρMax/ρMin from the center to an outer surface, in which the results for a polysilicon rod subjected to cleaning according to an embodiment is indicated by a solid line, and the results for a polysilicon rod not adopting cleaning according to the embodiment is indicated by a dotted line; and

FIG. 4 is a diagram illustrating the results of measuring an in-plane resistivity distribution when a single crystal is produced by the FZ method, in which white circles indicate the results according to Examples and black circles indicate the results according to Comparative Examples.

### DETAILED DESCRIPTION

The present embodiment provides a polysilicon rod in which an in-plane resistivity distribution in a radial direction of a single crystal ingot manufactured by a single crystallization FZ method is improved and a method for manufacturing the polysilicon rod, and particularly provides a high-purity polysilicon rod in which an in-plane resistivity distribution in a single crystal wafer having a diameter of 6 inches or more is improved and a method for manufacturing the same.

### Aspect of Present Invention

In order to obtain a polysilicon rod with improved RRG, a procedure for preventing contamination of a silicon core wire surface and in an initial stage of growth, which is an aspect, includes (1) wet etching before attachment to a reactor, (2) attachment of a silicon core wire to the reactor, (3) dry etching in the reactor, and (4) performing temperature management during initial growth of a polysilicon rod up to φ30 mm from before and after a reaction, and controlling the temperature of the silicon core wire to less than 1000° C. It is preferable to perform at least (3) in these procedures (1) to (4), it is more preferable to perform both (1) and (3), and it is particularly preferable to perform all of (1) to (4). The temperature of the silicon core wire in (4) can be observed by, for example, a measurement device using infrared rays.

An aspect of the present invention will be described in detail.

(1) Wet Etching Before Attachment to Reactor

The wet etching before attachment to a reactor is performed for the purpose of removing an oxide film of silicon and removing foreign matters on the surface. Performing the wet etching with a mixed acid of HF (hydrofluoric acid) and HNO₃ (nitric acid) to remove a damaged layer on the surface and hydrophobize the surface can delay the growth rate of the natural oxide film after the wet etching treatment.

After the wet etching, the cleaned silicon core wire is exposed to the atmosphere, an oxide film is gradually formed, and the silicon core wire comes into contact with particles in the air. To minimize the formation of the oxide film and contamination by particles in the air, it is preferable to start the attachment reaction to the reactor within 12 hours, more preferably within 8 hours, and particularly preferably within 4 hours. To prevent oxidation and contamination, it is also possible to use a storage container or the like. However, there is a possibility that contamination may be caused by the act of setting in the storage container. Thus, it is preferable to attach the silicone core wire to the reactor as soon as possible.

When it is difficult to take such an aspect, it is possible to prevent contamination of the surface of the silicon core wire by putting the surface to be in contact with the silicon core wire in a package subjected to a clean surface treatment in a clean atmosphere of class 100 and storing the core wire. In such a case, a plastic bag may be used, and a plastic bag after being naturally dried in a clean room after being washed with an acid aqueous solution (for example, an aqueous solution in which HF and HNO₃ are mixed in a ratio of 1:3 to 1:7) and rinsed may be used. As the bag, a bag made of low density polyethylene (LDPE), linear low density polyethylene (LLDPE), polyvinylidene fluoride (PVDF), or the like may be used.

As another method for preventing contamination, an ozone water treatment may be performed as soon as possible after wet etching, and a normal oxide film that is not a natural oxide film may be artificially formed. Using such a method can further prevent contamination. The ozone water treatment is desirably continuously performed after wet etching.

Thereafter, by sealing and storing the surface to be in contact with the silicon core wire in a package subjected to a clean surface treatment in a clean atmosphere to prevent contamination of the surface of the silicon core wire, storage can be made in a state where contamination can be more effectively prevented.

The oxide film attached to the surface of the silicon core wire by ozone water treatment needs to be removed before attachment to the reactor because the oxide film is difficult to be removed by etching treatment with a hydrogen halide. Thus, by etching the oxide film with HF (hydrofluoric acid), then cleaning with ultrapure water, and then rapidly attaching the silicon core wire to the reactor, it is possible to further prevent contaminants from adhering to the surface of the silicon core wire.

Alternatively, contaminants on the surface of the silicon core wire can be removed to the utmost limit by directly setting the silicon core wire with an oxide film attached by ozone water treatment in the reactor, setting the temperature to be lower than 1000° C., reducing and removing the oxide film under hydrogen atmosphere, thereafter once lowering the temperature of the silicon core wire, then raising again the temperature to a temperature at which the silicon core wire is treated by etching with a hydrogen halide, and performing etching.

Alternatively, it is possible to improve the quality and shorten the time for removing the oxide film by further performing a reduction treatment of the oxide film in the hydrogen atmosphere after the HF (hydrofluoric acid) etching.

(2) Attachment of Silicon Core Wire to Reactor

When the silicon core wire is attached to the reactor, impurity contamination due to the contact of a jig can be prevented by limiting the contact to only both ends and avoiding contact of the central part. The both ends that have contacted with other substances are cut out by processing the polycrystalline silicon taken out after the manufacture of the polycrystalline silicon so as not to affect the quality of FZ. Further, when diffusion of impurities from both ends becomes a problem, it is preferable to attach the contact part with a jig made of “clean silicon” having no influence of contamination. It is more preferable that the contact part can be replaced with clean silicon each time because impurities can be prevented from adhering to the contact part each time the contact part is attached. The silicon used for the contact part of the jig may have the same quality as the silicon core wire to be attached.

(3) Dry Etching in Reactor

Even when the silicon core wire is carefully attached in the reactor in this manner, contamination is inevitable because the work is performed in the atmosphere. Thus, it is preferable that the silicon core wire attached in the reactor is finally treated by etching with a hydrogen halide to remove impurities. Examples of the hydrogen halide include hydrogen chloride, hydrogen fluoride, and hydrogen bromide, and hydrogen chloride is preferable because it is easy to handle, inexpensive, and has less corrosion in the furnace.

The temperature at which the etching is performed is equal to or higher than a temperature at which a reaction between the hydrogen chloride used for the etching and silicon occurs, preferably higher than 300° C., more preferably 400° C. or more. Since it takes an etching time to obtain a sufficient etching amount because the etching rate decreases and it is not suitable for operation, the temperature is more preferably 500° C. or more. The upper limit temperature is set to a temperature not exceeding 1000° C., and is preferably 900° C. or less, more preferably 700° C. or less. As described above, when the temperature exceeds 1000° C., elution is more likely to occur from the inner wall surface of the reactor and the structure, which causes contamination. Thus, in the present embodiment, it is important to perform etching on the silicon core wire at a temperature of less than 1000° C.

To obtain an etching effect with a hydrogen halide such as hydrogen chloride at such a temperature, it is necessary to remove an oxide film of silicon. Thus, it is preferable to perform wet etching in advance for the purpose of removing the oxide film, and the procedure (1) corresponds to this wet etching. Etching the silicon core wire at a temperature lower than 1000° C. as in the procedure (3) can reduce the influence on the material in the reactor and more effectively remove impurities on the surface of the silicon core wire.

(4) Temperature Management During Initial Growth

The temperature during initial growth of the polysilicon rod up to φ30 mm from before and after the reaction is also desirably 1000° C. or less for the same reason. It is necessary to reduce the supply amount of the gas to prevent the silicon core wire from collapsing especially before the start of the reaction or immediately after the supply of the raw material. Thus, the proportion of the eluate of the impurities from the structure in the reactor to be mixed in the supply gas increases, and the impurity concentration of the supply gas increases. Thus, the amount of impurities mixed at the time of initial polysilicon rod growth increases, which causes a decrease in resistivity.

Usually, it is necessary to set the supply amount of the gas at the initial stage (immediately after the raw material supply) to such a degree that an air flow does not hit the silicon core wire and a crack does not occur in consideration of the size of the reactor, the length of the silicon core wire, the positions of the core wire and the gas supply nozzle, the kinetic energy of the gas emitted from the nozzle, and the like, and to prevent the polysilicon rod during the reaction from collapsing because of cracks. In the stable growth region of the CVD reaction (growth time zone corresponding to the middle to latter half of the reaction step), a gas of about 0.5 to 5 kmol/hr/m² is supplied with respect to the surface area of the silicon core wire. On the other hand, the initial gas supply amount is approximately 1/50 to 1/300 with respect to the supply amount of the stable growth region. The impurity concentration of the eluted impurities from the structure in the initial reactor is 50 to 300 times the stable growth region. Thus, the impurity concentration is overwhelmingly higher in the initial stage than in the stable growth region, and the polycrystalline silicon during the reaction is considerably affected by the elution of impurities generated from the reactor.

The inner wall of the reactor and the metal structure inside the reactor receive radiation from the growing polysilicon rod, and the metal surface temperature rises even during the CVD reaction. The chlorosilanes of the raw material and the reaction by-products react with the metal, and impurities such as dopants are eluted together with the metal chloride having a high vapor pressure. Thus, impurities are mixed in the CVD reaction at the initial stage of the reaction, which reduces the resistance of the polycrystalline silicon. Therefore, in order to make the in-plane resistivity distribution in a section of the polycrystalline silicon constant, it is more preferable that the silicon is grown at a rod temperature at the initial stage of the reaction of 1000° C. or less.

As a result of paying attention to the initial growth of the central part of the polysilicon rod to manufacture the polysilicon rod by such a method, the polysilicon rod according to the claims can be produced, and the single crystal silicon rod manufactured by a FZ method using the polysilicon rod can maintain favorable RRG with high resistance.

### Example 1

A silicon core wire is stored in a bag with less impurities to store the silicon core wire, but when the silicon core wire is stored for a long period of time, a large amount of impurities adhere to the surface of the silicon core wire.

Since a natural oxide film and impurities are present on the surface of the silicon core wire to be used, the natural oxide film and impurities are removed by wet etching and cleaning with pure water. A mixed acid of HF (hydrofluoric acid) and HNO₃ (nitric acid) (HF:HNO₃=1:5) was produced by using HF (hydrofluoric acid) having a hydrofluoric acid concentration of 50% and HNO₃ (nitric acid) having a nitric acid concentration of 70%. A silicon core wire was etched at 25° C. for 2 minutes using the mixed acid, and then washed with ultrapure water for 30 minutes.

Thereafter, the silicon core wire was dried in a clean space (with particles 100 or less), and immediately after drying, the upper end and the lower end of the silicon core wire were held with jigs so that nothing comes into contact with a linear motion part of the silicon core wire, and the silicon core wire was set in a reaction furnace, in order to shorten the time until the start of the CVD reaction (reaction by the Siemens process for manufacturing polycrystalline silicon) as much as possible. This can reduce natural oxidation and contamination of the silicon core wire. As for the resistivity of the silicon core wire itself to be used, a high-quality silicon core wire obtained by cutting out a FZ single crystal like the polysilicon rod to be manufactured was used.

The resistivity of the silicon core wire may be 3300 Ωcm or more, more preferably 4000 Ωcm or more, and particularly preferably 4500 Ωcm or more. The higher the resistivity of the silicon core wire, the higher the resistance value of the polysilicon rod grown by the CVD reaction. In this example, a silicon core wire having a resistivity of 4500 Ωcm was used.

After the silicon core wire (10 mmsq, resistivity 4500 Ωcm) was set in the reactor, the silicon core wire was replaced with a hydrogen gas through replacement with an inert gas. At this time, the oxygen concentration was set to 30 ppm or less, and the dew point was set to −50° C. or less. When electricity was passed through the silicon core wire to increase the current, the temperature of the silicon core wire started to rise. Hydrogen chloride (hydrogen base) was introduced at the time when the temperature of the silicon core wire reached 300° C., and the temperature was raised to a predetermined temperature. This predetermined temperature is described as the silicon core wire temperature in Table 1. After the temperature reached 900° C., which was a predetermined temperature, etching was performed for 5 minutes. As the hydrogen chloride to be used, anhydrous hydrogen chloride having a high purity of 99.999% or more was used in order to prevent the generation of the metal chloride described above. The etching amount of the surface of the silicon core wire was 15 μm. Through this step, a polysilicon rod having a small in-plane resistivity distribution can be obtained.

The etching temperature was set to a target temperature by energizing all the silicon core wires from the state in which the gas in the reactor immediately before the CVD reaction is replaced with hydrogen. The rod temperature during CVD is usually monitored by a radiation thermometer, and the applied voltage and current were adjusted using this radiation thermometer so that the temperature reaches a target temperature.

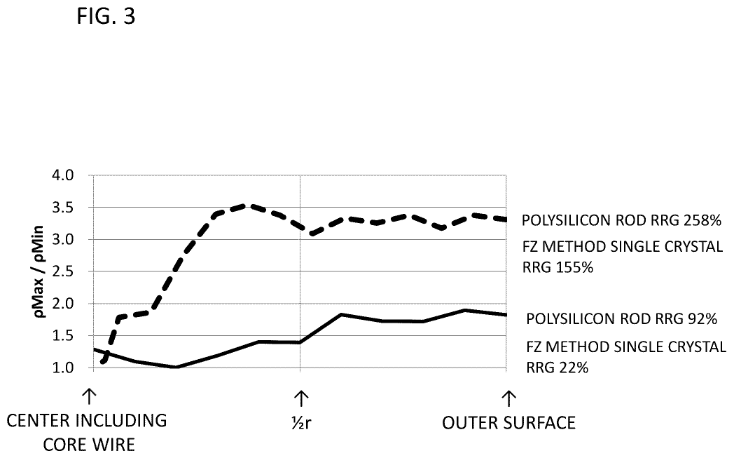

Etching was performed using a hydrogen chloride (99.999%) 30 mol % hydrogen base, and then a CVD reaction was performed at a temperature of the silicon core wire of 900° C. until the silicon core wire reached φ30 mm. Thereafter, a polysilicon rod was produced by a common manufacturing method, and the position where the resistivity reached a lowest resistivity was observed. As a result, it was confirmed that the lowest resistivity was present within 30 mm from the silicon core wire. This lowest resistivity was defined as silicon core wire central resistivity. The silicon core wire central resistivity was 3551 Ωcm. When polycrystalline silicon was grown by a common manufacturing method, the RRG was 66% when the diameter became 120 mm, and the RRG was 92% when the diameter became 140 mm. When this polysilicon rod was made into a FZ single crystal by a common method, the RRG of the FZ single crystal was as good as 22% (see FIG. 3). The “outer surface” at the right end of FIG. 3 indicates 140 mm.

### Example 2

A silicon core wire as in Example 1 was set in a reaction vessel. After the temperature reached a predetermined temperature of 700° C., etching was performed for 5 minutes. The etching amount was 0.1 μm. Etching was performed with a hydrogen chloride (99.999%) 30 mol % hydrogen basis in the same manner as in Example 1, then the temperature of the silicon core wire was set to 700° C. A CVD reaction was then performed by a common method until the diameter reached φ30 mm. Thereafter, a polysilicon rod was produced by a common manufacturing method, and the position where the resistivity reached the lowest resistivity was observed. As a result, the silicon core wire central resistivity was 4329 Ωcm. When polycrystalline silicon was grown by a common manufacturing method, the RRG was 36% when the diameter became 120 mm, and the RRG was 77% when the diameter became 140 mm. Thus, it was confirmed that the value of RRG in Example 2 in which etching was performed at 700° C. was able to be reduced to be lower than in the case of Example 1 in which etching was performed at 900° C., and a beneficial result was able to be obtained.

### Comparative Example 1

A silicon core wire as in Example 1 was set in a reaction vessel. After the temperature reached a predetermined temperature of 1100° C., etching was performed for 3 minutes. The etching amount was 84 μm. Etching was performed with a hydrogen chloride (99.999%) 30 mol % hydrogen basis in the same manner as in Example 1, then the temperature of the silicon core wire was set to 1100° C. A CVD reaction was performed by a common method until the diameter reached φ30 mm. Thereafter, a polysilicon rod was produced by a common manufacturing method, and the position where the resistivity reached the lowest resistivity was observed. As a result, the lowest resistivity was 2189 Ωcm. When polycrystalline silicon was grown by a common manufacturing method, the RRG was 97% when the diameter became 120 mm, and the RRG was 142% when the diameter became 140 mm.

### Comparative Example 2

A same silicon core wire as in Example 1 except that wet etching was not performed was set in a reaction furnace unlike Example 1, and thereafter, a polysilicon rod was produced by a common manufacturing method, and a position where the resistivity reached the lowest resistivity was observed. As a result, it was found that a lot of impurities present on the surface were diffused into the silicon core wire unless wet etching was performed. Thus, ρMin was present inside the silicon core wire, and the lowest resistivity thereof was 1697 Ωcm. When polycrystalline silicon was grown by a common manufacturing method, the RRG was 206% when the diameter became 120 mm, and the RRG was 258% when the diameter became 140 mm. When this polysilicon rod was made into a FZ single crystal by a common method, the RRG of the FZ single crystal was as bad as 155% (see FIG. 3).

The results in Examples and Comparative Examples are shown in Table 1 below.

TABLE 1

| | Temperature of | Etching | Etching | Lowest |
|---|---|---|---|---|
| | silicon core | time | amount | resistivity |
| | wire (° C.) | (min) | (μm) | (Ωcm) |
| Comparative | 1100 | 3 | 84 | 2189 |
| Example 1 | | | | |
| Example 1 | 900 | 5 | 15 | 3551 |
| Example 2 | 700 | 5 | 0.1 | 4329 |
| Comparative | — | — | — | 1697 |
| Example 2 | | | | |

Method for Measuring In-Plane Resistivity Distribution of Polysilicon Rod

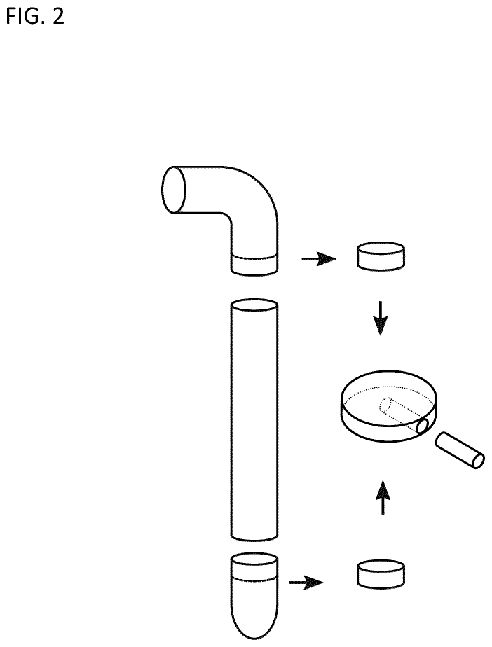

As illustrated in FIG. 2, the upper side and the lower side of the polysilicon rod taken out from the CVD reactor were cut, and the vicinity of the cut surface outside the effective length at the time of production was cored from the outer periphery in the direction of the silicon core wire with a core drill to produce a sample including the outer periphery and the silicon core wire (JIS H 0615 2021 4.2 Production of Polycrystalline Silicon Sample). Using the sample thus produced, single crystallization was performed from the outer peripheral direction by a FZ method. The resistivity of the finished single crystal was measured from the outer periphery to the part corresponding to the silicon core wire by a four-probe method. The in-plane resistivity distribution of the polysilicon rod can be thus confirmed. At this time, a true value on the polysilicon rod cannot be obtained because of segregation of impurities by the FZ method, but by performing FZ from a direction of the outer periphery across the silicon core wire, a change in resistivity in the vicinity of the silicon core wire, which should be particularly noted, can be grasped. The index RRG representing the in-plane resistivity distribution is a relative evaluation, and the variation in resistivity can be evaluated.

RRG (Radial Resistivity Gradient) is used as an index representing the in-plane resistivity distribution of the silicon single crystal substrate, which is expressed by the following Formula, where ρMax is the maximum value of the resistivity in the plane radial direction, and ρMin is the minimum value.

RRG=(ρMax−ρMin)/ρMin×100(%) (Formula 1)

It is typically used as an index representing the in-plane resistivity distribution of a silicon single crystal substrate, but in the present invention, it is adopted as an index representing the resistivity distribution in the radial direction of the polysilicon rod.

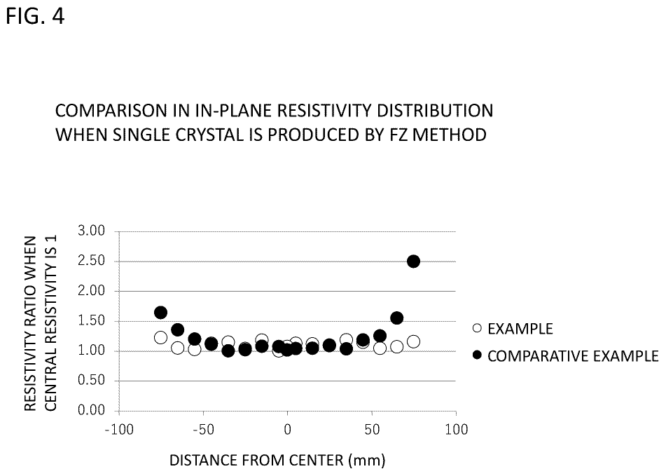

A polysilicon rod that has been cleaned according to the embodiment is indicated by a solid line in FIG. 3. The drop of the resistivity near the center including the silicon core wire is improved and shows a uniform in-plane resistivity distribution of the polysilicon rod with respect to the rod growth direction. A single crystal was produced by a FZ method using this silicon rod as a raw material, and the in-plane resistivity distribution was measured. As a result, the in-plane resistivity became uniform, and improvement was observed (see FIG. 4). In a FZ method in which a single crystal was produced for comparison, an operation of improving the in-plane resistivity distribution was not performed, and the FZ method was performed without doping.

As a result of making the vicinity of the outer peripheral part of the silicon core wire have a high resistance, the resistance in the vicinity of the outer peripheral part of the silicon core wire was improved to 3551 Ωcm, and thus, the diameter of the FZ single crystal was 140 mm, and the RRG was improved to 22% (Example 1).

Such a high-resistance FZ single crystal having a low RRG can be used for a base of a device using the MEMS technology, and is suitable as a supporting base of a terahertz element of a terahertz device. The high-resistance FZ single crystal, being a homogeneous and high-quality raw material, can form an ingot in which phosphorus is uniformly dispersed by the NTD method even when the diameter is increased, which is favorable for use in a high-voltage power semiconductor.

In addition, when the resistivity distribution can be improved and the resistivity can be increased in this manner, a polysilicon rod with a higher resistance is manufactured by the method of the present application using the manufactured high-resistance and high-quality FZ single crystal silicon as a silicon core wire. Since the center resistivity of the silicon core wire is high, the RRG is reduced, and a higher-quality FZ single crystal can be manufactured without lowering the production efficiency.

### REFERENCE SIGNS LIST

1a polysilicon rod
1b unmelted part
2 single crystal silicon
3 melted part
4 coil

1. A polysilicon rod having a diameter of 120 mm or more, the polysilicon rod having a lowest resistivity of 3300 Ωcm or more and an RRG of 100% or less.

2. The polysilicon rod according to claim 1, wherein the lowest resistivity is positioned within 30 mm from a silicon core wire toward an outer periphery,
the polysilicon rod having a highest resistivity at a position of more than 30 mm from the silicon core wire toward the outer periphery.

3. The polysilicon rod according to claim 1, wherein the RRG is 50% or less.

4. A polysilicon rod having a diameter of 140 mm or more, the polysilicon rod having a lowest resistivity of 3300 Ωcm or more and an RRG of 150% or less.

5. The polysilicon rod according to claim 4, wherein the lowest resistivity is positioned within 30 mm from a silicon core wire toward an outer periphery,
the polysilicon rod having a highest resistivity at a position of more than 30 mm from the silicon core wire toward the outer periphery.

6. The polysilicon rod according to claim 4, wherein the RRG is 100% or less.

7. A method for manufacturing a polysilicon rod according to claim 1, the method comprising:
a step of setting a silicon core wire in a reactor; and
a step of etching the silicon core wire with a hydrogen halide in a situation where the silicon core wire has a temperature of more than 300° C. but not more than 1000° C.

8. The method according to claim 7, wherein the step of etching with the hydrogen halide is performed at a temperature of 800° C. or less.

9. The method according to claim 7, further comprising a step of removing an oxide film and impurities on a surface of the silicon core wire by wet etching before setting the silicon core wire in the reactor.

10. A method for manufacturing a polysilicon rod according to claim 1, the method comprising:
a step of removing an oxide film and impurities on a surface of a silicon core wire by wet etching;
a step of setting the silicon core wire in a reactor;
a step of etching the silicon core wire with a hydrogen halide in a situation where the silicon core wire has a temperature of more than 300° C. but not more than 800° C.; and
a step of depositing polysilicon through a CVD reaction.

11. A method for manufacturing a polysilicon rod according to claim 4, the method comprising:
a step of setting a silicon core wire in a reactor; and
a step of etching the silicon core wire with a hydrogen halide in a situation where the silicon core wire has a temperature of more than 300° C. but not more than 1000° C.

12. A method for manufacturing a polysilicon rod according to claim 4, the method comprising:
a step of removing an oxide film and impurities on a surface of a silicon core wire by wet etching;
a step of setting the silicon core wire in a reactor;
a step of etching the silicon core wire with a hydrogen halide in a situation where the silicon core wire has a temperature of more than 300° C. but not more than 800° C.; and
a step of depositing polysilicon through a CVD reaction.
